(19) United States
(12) Patent Application Publication
(10) Pub. No.: US 2008/0308881 A1
(43) Pub. Date: Dec. 18, 2008

(54) Method for Controlled Formation of a Gate Dielectric Stack

(75) Inventors: Stefan De Gendt, Wijnegem (BE); Lars-Ake Ragnarsson, Leuven (BE); Sven Van Elshocht, Heverlee (BE); Shih-Hsun Chang, Hsinchu (TW); Christoph Adelmann, Leuven (BE); Tom Schram, Rixensart (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignees: INTERUNIVERSITAIR MICROELEKTRONICA CENTRUM (IMEC), Leuven (BE); TAIWAN SEMICONDUCTOR MANUFACTURING COMPANY, LTD., HsinChu (TW)

(21) Appl. No.: 11/972,615

(22) Filed: Jan. 10, 2008

Related U.S. Application Data
(60) Provisional application No. 60/879,693, filed on Jan. 10, 2007.

(30) Foreign Application Priority Data
Jun. 29, 2007 (EP) 07111486.2
Jul. 26, 2007 (EP) 07113225.2

(51) Int. Cl. H01L 21/28; H01L 29/78; H01L 29/92; H01L 21/02

(52) U.S. Cl. 257/410; 438/591; 257/532; 438/381; 257/E21.192; 257/E29.255; 257/E29.343; 257/E21.008

(57) ABSTRACT

The present disclosure relates to methods for forming a gate stack in a MOSFET device and to MOSFET devices obtainable through such methods. In exemplary methods described herein, a rare-earth-containing layer is deposited on a layer of a silicon-containing dielectric material. Before these layers are annealed, a gate electrode material is deposited on the rare-earth-containing layer. Annealing is performed after the deposition of the gate electrode material, such that a rare earth silicate layer is formed.

The present application claims the priority of U.S. Provisional Patent Application No. 60/879,693, filed Jan. 10, 2007, European Patent Application No. EP 07111486.2, filed on Jun. 29, 2007, and European Patent Application No. EP 07113225.2 filed on Jul. 26, 2007.

### BACKGROUND

The present disclosure relates to semiconductor process technology and devices. In particular, the present disclosure relates to a method for forming a gate stack in a MOSFET device and the MOSFET device obtainable by such a method.

Ono et al. (Appl. Phys. Lett., 78, 1832 (2001)) have described that the rare earth (RE) elements, for example lanthanum, in contact with SiO₂ in an oxygen-containing ambient, react to form a silicate when heated to sufficiently high temperatures.

Depending on the nature of the element, the intensity of the silicate formation will vary. As a result of this, silicate formation may have different consequences.

One consequence is the consumption of the interface region between the rare earth element and the silicon-oxide resulting in a reduction of the equivalent oxide thickness (EOT) as observed by Lichtenwahlner et al. (J. Appl. Phys., 98, 024314 (2005)).

Another consequence is the shift of the threshold voltage towards lower values as reported by L. Pantisano et al. (Appl. Phys. Lett., 89, 113505 (2006)), when these rare earth materials are integrated in the gate stack as a cap layer of monolayer(s) thickness.

### SUMMARY

The present disclosure provides methods for forming a gate stack in a MOSFET device. One such method comprises the steps of:
forming, on a semiconductor substrate, at least one layer of a dielectric material, the upper layer comprising (or consisting of) a Si-containing dielectric material (Si-CDM),
depositing (immediately) on the Si-CDM, at least one rare earth oxide (REO) layer,
depositing (immediately) on the REO layer, at least one layer of a suitable material for forming a metal gate electrode, and
after having deposited the material suitable for forming a metal gate electrode on he REO layer, annealing (for obtaining a reaction, at least partially, between the Si-CDM and the REO layer), whereby a rare earth silicate (RES) layer is formed,
   wherein there is no annealing step (resulting in RES formation) before having deposited the material suitable for forming a metal gate electrode on the REO layer.

In one disclosed method, no annealing step is performed before the deposition of the metal gate.

Preferably, an annealing step is performed immediately after the metal gate deposition.

Preferably, the annealing step is a PDA step (post-deposition annealing step).

The annealing step can be a RTA step (Rapid Thermal Anneal step).

Preferably (and alternatively), the annealing step can be performed after spacer definition. A method can further comprise, before the annealing step, the steps of polySi deposition, gate patterning, and spacer formation.

The annealing step can be a source/drain RTA step after spacer definition.

The annealing step can comprise a source/drain RTA step and a PDA step, after spacer definition.

In one disclosed method, the annealing step is preferably performed at a temperature higher than about 600° C., preferably between about 600° C. and about 1200° C., more preferably between about 600° C. and about 1000° C.

More preferably, the annealing step is performed at a temperature higher than about 800° C., preferably between about 800° C. and about 1200° C., more preferably between about 800° C. and about 1000° C.

Preferably, the REO and the Si-CDM are provided in a ratio REO:(REO+Si(CDM)) between about 0.05 and about 0.4, more preferably between about 0.1 and about 0.4, even more preferably between about 0.2 and about 0.35, and even more preferably between about 0.2 and about 0.3.

In one method described herein, at least one layer of a dielectric material consists of Si-CDM. Preferably, at least one layer comprising (or consisting of) a Si-CDM is formed on the semiconductor substrate.

The Si-CDM layer can comprise (or consist of) any suitable high-k material (i.e. any suitable material the dielectric constant of which is higher than the dielectric constant of SiO₂; i.e. k>k_{SiO2}).

Preferably, at least one layer of Si-CDM comprises (or consists of) SiO₂.

In one embodiment, at least one of the layers of Si-CDM can comprise or further comprise nitrogen. More particularly, at least one layer of Si-CDM comprises (or consists of) SiON.

Preferably, the Si-CDM is formed or deposited by MOCVD, ALD, AVD or PVD deposition technique.

At least one layer of REO can comprise (or consist of) any of La, Y, Pr, Nd, Sm, Eu, Gd, Dy, Er, or Yb, or any combination of 2, 3 or more thereof. More particularly, at least one layer of REO can comprise (or consist of) any of La-, Y-, Pr-, Nd-, Sm-, Eu-, Gd-, Dy-, Er-, or Yb-based oxides, or any combination of 2, 3 or more thereof.

Preferably, a layer of REO can comprise (or consist of) La and/or Dy based oxides. More preferably, the REO layer comprises (or consists of) dysprosium oxide. Preferably, the REO layer is deposited by MOCVD, ALD, AVD or PVD deposition technique. A layer of REO can result from the oxidation of a layer of a rare earth element.

A layer of Si-CDM and/or a layer of REO can further comprise a modulator element, such as Al, Hf, or Sc. The modulator can be added to the REO layer for increasing the thermal stability of the layer. In particular, the modulator element can be added to a Si-CDM layer and/or to the REO layer for enhancing or reducing the RES formation. More particularly, Hf and Sc hinder the RES formation; whereas Al is an enhancer of RES formation.

Preferably, the REO layer comprises (or consists of) dysprosium scandate.

Preferably, the modulator is added to the REO layer in a ratio Modulator: (Modulator+RE) of about 50%.

The modulator can be an enhancer element (such as Al), whereby the intermixing is enhanced. For example, Al can be added to the REO in a ratio Al:(Al+RE) smaller than (about) 75%.

Preferably, the metal gate electrode comprises (or consists of) W, Ta, Ti, Ru, Pt and/or Mo, preferably TiN, TaN and/or Ru.

Preferably, the substrate comprises (or consists of) a Ge, SiGe, GaAs, and/or InP layer.

The present disclosure further describes methods for reducing the EOT of a gate stack in a MOSFET device, by capping a Si-containing dielectric layer with a REO and annealing (forming a RES layer) after depositing a metal gate electrode. These methods for reducing the EOT of a gate stack in a MOSFET device can comprise the steps described herein for forming a gate stack in a MOSFET device.

In particular, the EOT can be reduced by at least 0.1 nm EOT when the ratio REO:(REO+Si(CDM)) is comprised between about 0.05 and about 0.4, more particularly between about 0.1 and about 0.4, even more particularly between about 0.2 and about 0.35, and even more particularly between about 0.2 and about 0.3.

Alternatively, in a second embodiment, instead of the REO formation, a method can be carried out with the deposition of a layer of a rare earth element (RE element), the oxidation of which is prevented. More particularly, the RE layer can be deposited in-situ, i.e. with no vacuum break between the RE deposition and the metal gate deposition.

In that embodiment, the RES results from the annealing of the Si-CDM layer and the RE layer.

More particularly, a method for forming a gate stack in a MOSFET device, according to this second embodiment can comprise the steps of:
forming, on a semiconductor substrate, at least one layer of a dielectric material, the upper layer comprising a Si-containing dielectric material (Si-CDM), preferably SiO₂ or SiON,
depositing on the Si-CDM at least one rare earth (RE) layer,
depositing on the RE layer, at least one layer of a suitable material for forming a metal gate electrode, and
after having deposited the material suitable for forming a metal gate electrode on the RE layer, annealing (for obtaining a reaction, at least partially, between the Si-CDM and the RE layer), whereby a rare earth silicate (RES) layer is formed,
   wherein oxidation of the RE layer is prevented (preferably by maintaining the vacuum until the layer of a suitable material for forming a metal gate electrode has been deposited), and wherein there is no annealing step before having deposited the material suitable for forming a metal gate electrode on the RE layer.

The other conditions and parameters used herein also apply to that embodiment.

Methods as described herein can also be used to form capacitors, such as metal-insulator-metal capacitors, in which the dielectric stack constitutes the dielectric part of such capacitor. One example of such a method comprises the steps of:
forming, on a material suitable for forming an electrode, at least one layer comprising (or consisting of) a Si-CDM,
depositing (immediately) on the Si-CDM, at least one REO or RE layer,
depositing (immediately) on the REO or RE layer, at least one layer of a material suitable for forming an electrode, and
after having deposited the material suitable for forming an electrode on the REO or RE layer, annealing (for obtaining a reaction, at least partially, between the Si-CDM and the REO or RE layer), whereby a rare earth silicate (RES) layer is formed,
   wherein there is no annealing step (resulting in RES formation) before having deposited the material suitable for forming an electrode on the REO or RE layer.

The present disclosure further describes embodiments of a semiconductor device obtainable by the methods described herein. One such semiconductor device is a capacitor, such as metal-insulator-metal capacitor.

Another such semiconductor device is a MOSFET device. In one embodiment, the MOSFET device comprises:
a semiconductor substrate,
a gate dielectric comprising (or consisting of) at least one layer of a dielectric material, the upper layer comprising (or consisting of) a Si-CDM,
upon the Si-CDM, a RES layer, and
upon the RES layer, a metal gate electrode,
   wherein the RES layer results from the annealing of the Si-containing dielectric material and the REO or RE layer, the annealing being performed only after having deposited the metal gate electrode.

A MOSFET device as described herein can further comprise unreacted REO or unreacted RE. A REO or RE layer can remain between the RES and the metal gate electrode.

A MOSFET device as described herein can further comprise a polySi layer on the metal gate electrode.

Preferably, at least one layer of dielectric material consists of Si-CDM.

Preferably, at least one layer of Si-CDM comprises SiO₂, SiON, HfSiO, or HfSiON.

More preferably, at least one layer of Si-CDM consists of SiO₂, SiON, HfSiO, or HfSiON.

Preferably, the REO or RE layer comprises (or consists of) any of La, Y, Pr, Nd, Sm, Eu, Gd, Dy, Er, Yb or any combination of 2, 3 or more thereof.

More preferably, the REO layer comprises (or consists of) any of La-, Y-, Pr-, Nd-, Sm-, Eu-, Gd-, Dy-, Er-, and Yb- based oxides or any combination of 2, 3 or more thereof. Even more preferably, the REO layer comprises (or consists of) any of La and/or Dy based oxides, and more particularly dysprosium oxide, or dysprosium scandate.

Preferably, the metal gate electrode comprises (or consists of) W, Ti, Ta, Pt, Ru and/or Mo, preferably TiN, TaN and/or Ru.

Preferably, the substrate comprises (or consists of) a Ge, SiGe, GaAs, and/or InP layer.

### BRIEF DESCRIPTION OF THE DRAWINGS

FIG. 1(a) shows the physical thickness variation of the as deposited gate dielectrics upon anneal at different temperatures.

FIG. 1(b) shows the thickness variation of the as deposited ALD La₂O₃ upon different anneal steps approximately from 600° C. to 1000° C.

FIG. 2 shows the normalized thickness increase (t_{annealed}−tdep)/t_{dep} for DyScOₓ layers annealed in O₂ (: circle) or N₂ (▴: triangle), where t_{annealed} is the layer thickness after a thermal anneal at about 1000° C. and t_{dep} is the as-deposited thickness of the layer.

FIG. 3 shows the normalized thickness increase for an about 10 nm DyScOₓ layer after different thermal treatments (temperature and time).

FIG. 4 shows the normalized thickness increase (t_{annealed}−t_{dep})/t_{dep} (: circle) and absolute thickness increase (▴: triangle) after 1000° C. anneal for a DyScOx layer as function of the as-deposited thickness.

FIG. 5 shows the normalized thickness increase (t_{annealed}−t_{dep})/t_{dep} after a 1000° C. anneal for DyScOx layers as function of the anneal time: Dy-rich (about 75% Dy) (: circle); Sc-rich (about 25% Dy) (▪: square).

FIG. 6 shows the relative thickness increase (%) as function of the Dy concentration (%) for two different compounds: DyHfOx (▪: square) and DyScOx (: circle).

FIG. 7 presents the threshold voltage (Vt) shift for Dy-based and Sc-based oxides and a combination thereof.

In FIG. 8(a), as a demonstration, a SiON dielectric film of 2 nm thickness has been capped by 1 nm of Dy₂O₃ and capped with a TaN metal electrode. After application of a junction activation thermal budget (1030° C.), a gate stack EOT has been extracted, clearly less than the original 2 nm SiON. A reduction in EOT from about 1.8 nm down to 1.3 nm EOT has been observed, as well as a reduction in Vt as shown in FIG. 8(b).

FIG. 9 shows the effects of Dy₂O₃ cap thicknesses on the EOT of SiON/Dy₂O₃/TaN.

FIG. 10 shows the EOT and eWF of SiO(N)/Dy₂O₃/TaN as a function of Dy₂O₃/(Dy₂O₃+SiO(N)) thickness ratio.

FIG. 11 shows the EOT and eWF of SiO(N)/Dy₂O₃/TaN with various thermal budgets and annealing sequences.

FIGS. 12(a)-(d) illustrate steps in a method as described herein.

In FIG. 12(a), (a) before a PDA annealing, the stack of layers comprises the substrate (1), the Si-CDM (2, 2a), the REO (4) and the metal gate (5).

In FIG. 12(b), after the PDA annealing of the stack of layers as illustrated in FIG. 12(a), the resulting stack of layers comprises the substrate (1), the Si-CDM (2a), the RES (3), possibly remaining REO (4a), and the metal gate (5).

In FIG. 12(c), before the annealing step, the stack of layers comprises the substrate (1), the Si-CDM (2, 2a), the REO (4), the metal gate (5), the polySi (6) and the spacers (7).

In FIG. 12(d), after the annealing step (performed after spacers definition), the resulting stack of layers comprises the substrate (1), the Si-CDM (2a), the RES (3), possibly remaining REO (4a), the metal gate (5), the polySi (6) and the spacers (7).

### DETAILED DESCRIPTION

The present disclosure provides a method for forming a gate stack in a MOSFET device, comprising the steps of:
forming, on a semiconductor substrate, at least one layer of a dielectric material (2, 2a), the upper layer comprising (or consisting of) a Si-CDM,
depositing (preferably immediately) on the Si-CDM, at least one rare earth oxide (REO) layer (4),
depositing (preferably immediately) on the REO layer (4), at least one layer of a suitable material for forming a metal gate electrode (5), and
after having deposited the material suitable for forming a metal gate electrode on the REO layer, annealing (for obtaining a reaction, at least partially, between the Si-CDM and the REO layer), whereby a rare earth silicate (RES) layer is formed,
   wherein there is no annealing step (resulting in RES formation) before depositing the material suitable for forming a metal gate electrode on the REO layer.

In at least some of the embodiments disclosed herein, the anneal step (for RES formation) takes place only after the metal gate electrode has been deposited on the REO. Such embodiments have demonstrated a surprising result: exceptional results in terms of Equivalent Oxide Thickness (EOT) reduction and effective work function (eWF) shift.

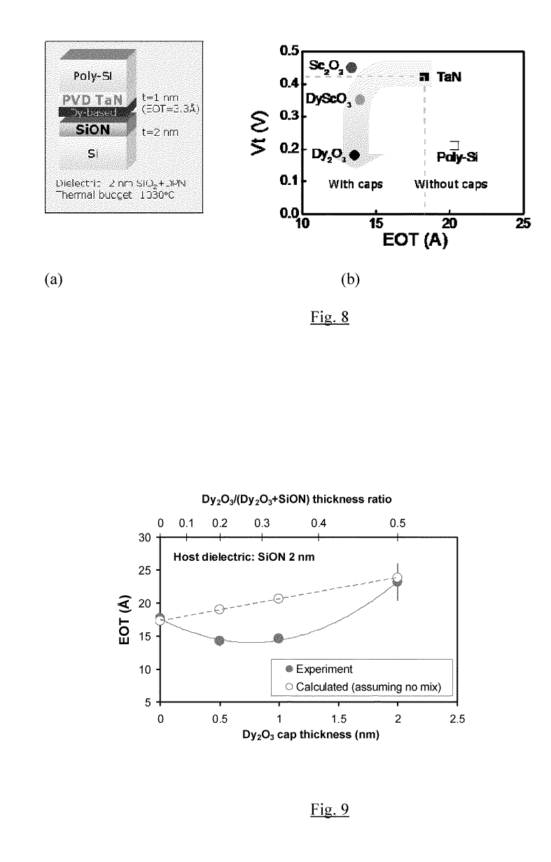

At least some of the embodiments disclosed herein make use of another surprising discovery: there is an optimum ratio REO/(REO+SiCDM) for which the EOT is the lowest (see FIG. 9). It was not expected that the EOT would increase when departing away from that optimum REO/(REO+Si-CDM) ratio in either direction.

FIG. 9 shows the effect of Dy₂O₃ thickness on the EOT of SiON/Dy₂O₃ stacks with a fixed SiON thickness (2 nm).

If one makes the assumption that Dy₂O₃ and SiON do not intermix, one can calculate that the EOT (open circles in FIG. 9) is expected to increase with the Dy₂O₃ cap thickness.

However, the experimental result shows that the EOT actually decreases from 1.8 nm to 1.4 nm (18 to 14 Å) when the SiON is capped with 0.5- and 1-nm Dy₂O₃.

Then, when the Dy₂O₃ thickness increases to 2 nm, the EOT increases again, agreeing with the calculated value assuming no mixing.

This is believed to indicate that intermixing between Dy₂O₃ and SION occurs at significant levels only at certain Dy₂O₃/(Dy₂O₃+SiO₂) thickness ratios. As seen in FIG. 9, The optimal Dy₂O₃/(Dy₂O₃+SiO₂) thickness ratio for minimal EOT is between about 0.2 and about 0.4.

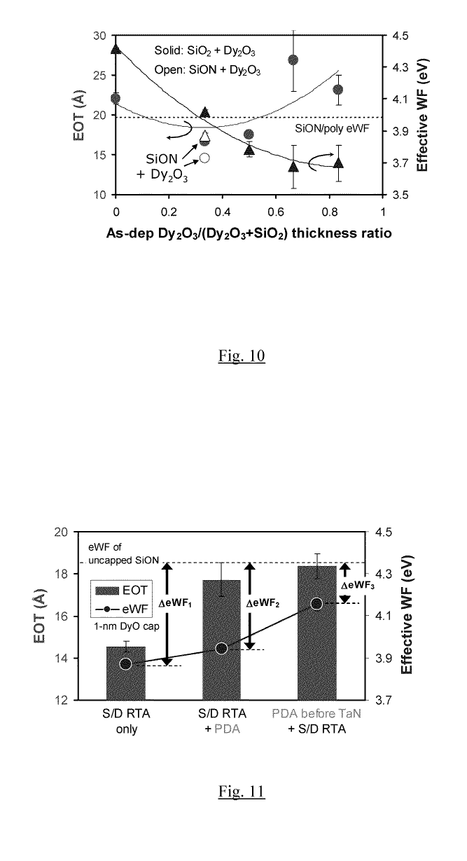

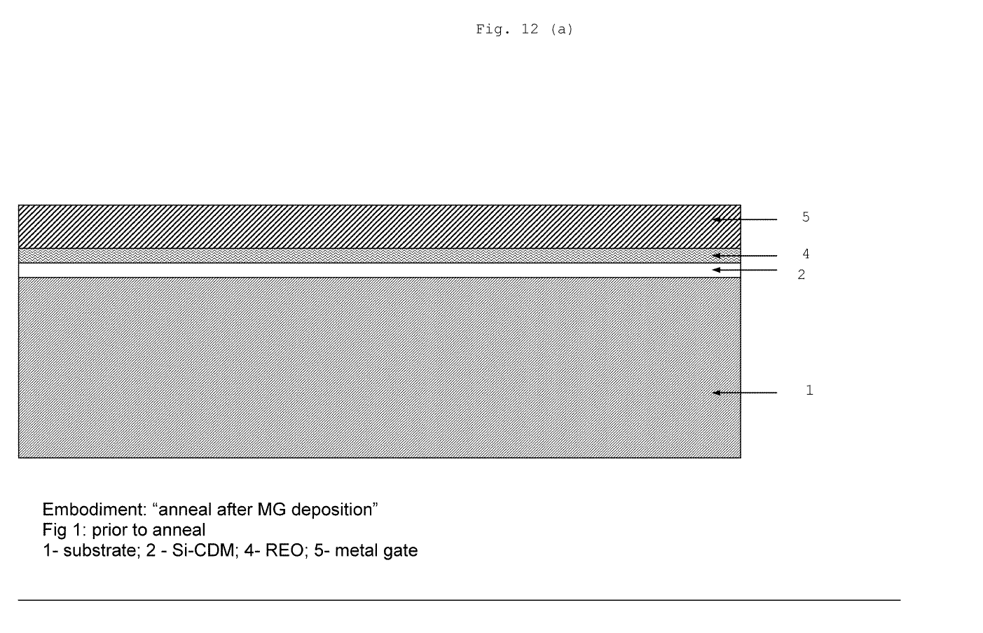

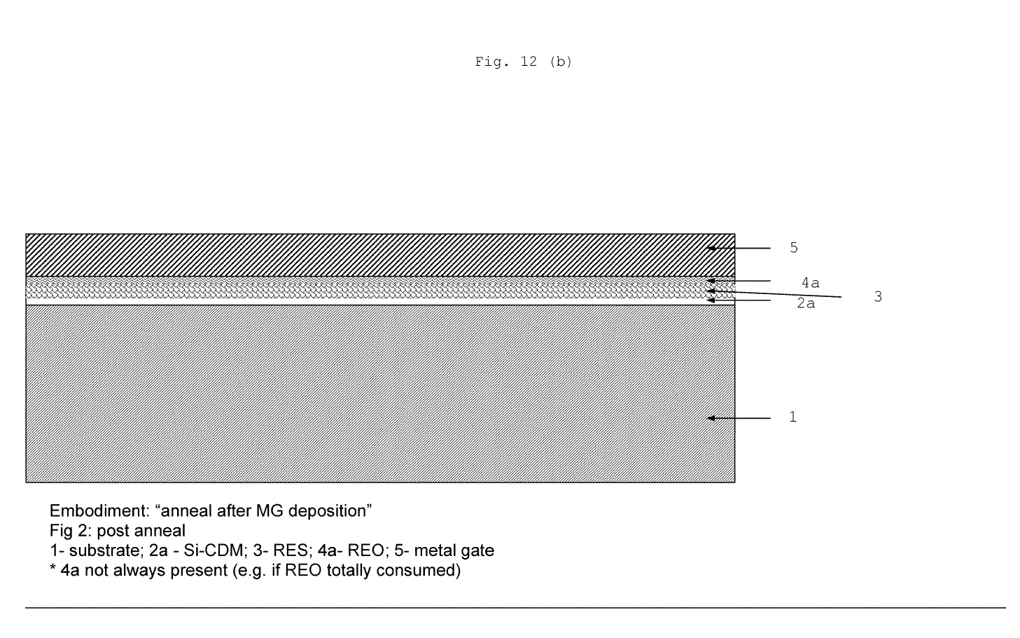

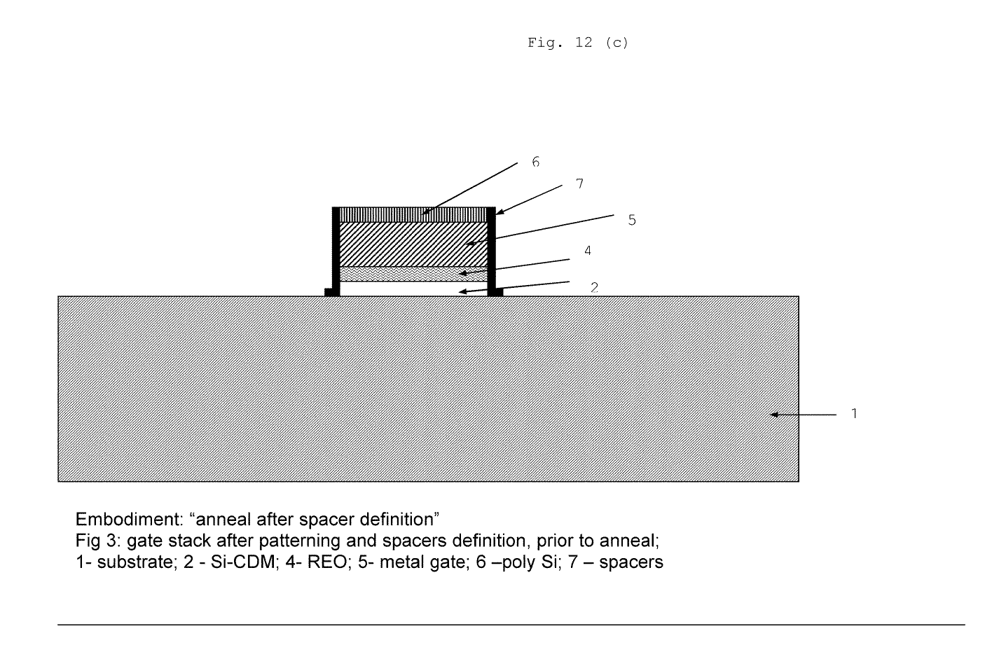

FIG. 10 shows the effect of Dy₂O₃/(Dy₂O₃+SiO₂) thickness ratio on the EOT of SiON/Dy₂O₃ stacks with a fixed total Dy₂O₃+SiO₂ thickness (3 nm).

The EOT of the SiO₂/Dy₂O₃ stack is a function of the Dy₂O₃/(Dy₂O₃+SiO₂) thickness ratio.

The smallest EOT is obtained at a ratio comprised between about 0.3 and about 0.4, corresponding to an EOT reduction of 0.5 nm (5 Å) as compared to the uncapped SiO₂.

However, with the Dy₂O₃/(Dy₂O₃+SiO₂) thickness ratios of 0.6 and above, the EOT increases and exceeds that of the uncapped SiO₂.

Unlike EOT, which exhibits a parabolic relationship with the Dy₂O₃/(Dy₂O₃+SiO₂) thickness ratio, the effective work function (eWF) is inversely proportional to the ratio.

The eWF decreases from 4.4 to 3.7 eV as the Dy₂O₃/(Dy₂O₃+SiO₂) thickness ratio increases from 0 to 0.7, and stabilizes at 3.7 eV with a ratio higher than 0.7.

The optimal Dy₂O₃/(Dy₂O₃+SiO₂) thickness ratio is about 0.3 where the EOT reduction is maximized and the eWF is comparable to that of the SiON/poly reference (4.0 eV).

FIG. 10 also shows that when nitrogen is added in SiO₂, the EOT and eWF decrease by 0.2 nm (2 Å) and 150 meV, respectively, as compared to the SiO₂/Dy₂O₃ stack at the same Dy₂O₃/(Dy₂O₃+SiO₂) thickness ratio. The EOT decrease may result from an increased dielectric constant or enhanced Dy₂O₃−SiO(N) intermixing due to the nitrogen incorporation.

The eWF decrease may result from the positive charges induced by the nitrogen incorporation which was also seen on the HfSiO(N)/Ta₂C stack.

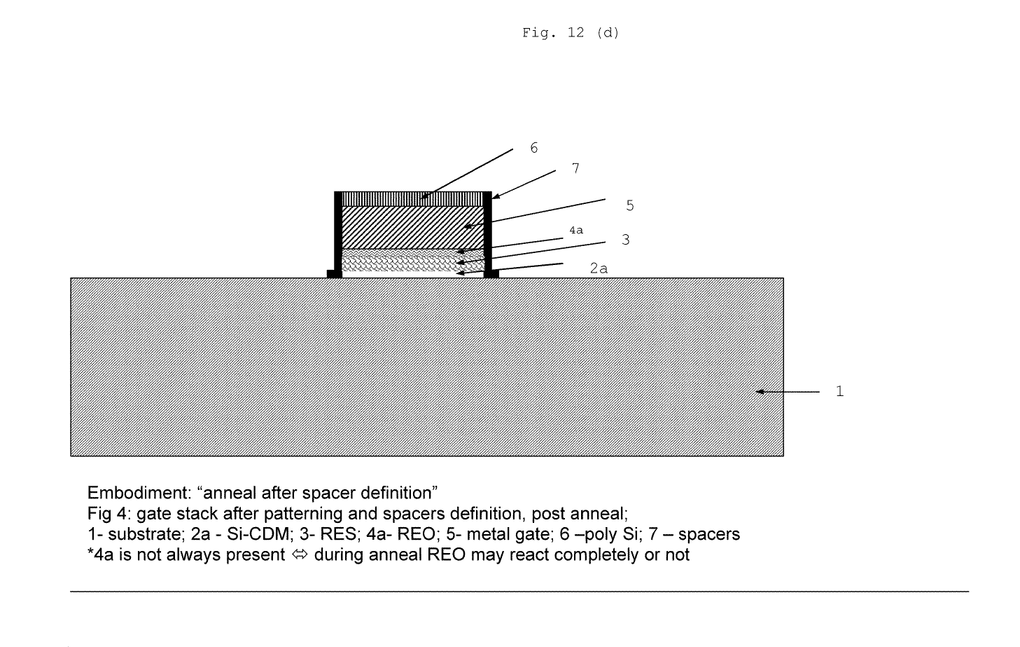

FIG. 11 shows the EOT and the eWF of Dy₂O₃-capped SiON from various thermal budgets and annealing sequences.

Besides the standard activation anneal (“S/D RTA”) at 1030° C., an additional post-deposition anneal (PDA) at 1050° C. was performed either after the S/D RTA (“S/D RTAS+PDA”) or before the metal gate deposition (“PDA before TaN+S/D RTA”).

By comparing “S/D RTA only” and “S/D RTAS+PDA,” it can be shown that an additional PDA increases the eWF only slightly, rendering the eWF shift (ΔeWF₂) slightly smaller.

However, when the PDA is performed on the as-deposited Dy₂O₃ before metal gate deposition (“PDA before TaN+S/D RTA”), the eWF shift (ΔeWF₃) decreases substantially by 220 meV.

This shows that to achieve the maximal eWF tuning, the (high-temperature) anneal should be performed after the Dy₂O₃ cap is covered/enclosed, in this example, by the metal gate, poly electrode, and spacer.

According to a preferred embodiment, a method for forming a gate stack in a MOSFET device comprises the steps of:
forming, on a semiconductor substrate, one layer of SiO₂ or one layer of SiON,
forming or depositing on the SiO₂ or SiON, one dysprosium scandate layer, or one lanthanum oxide layer, or preferably one dysprosium oxide layer,
depositing on the REO layer, at least one layer of a suitable material for forming a metal gate electrode, preferably a TaN layer, and
after having deposited the material suitable for forming a metal gate electrode on the REO layer, annealing (for obtaining a reaction, at least partial, between the SiO₂ or SiON layer and the REO layer, whereby a rare earth silicate (RES) layer is formed,
   wherein there is no annealing step before having deposited the material suitable for forming a metal gate electrode on the REO layer.

Depending on the substrate, the annealing step is performed at a temperature preferably between 600° C. and 1200° C., more preferably between 600° C. and 1000° C.

Preferably, the REO and the SiO₂ (or SiON) are provided in a ratio REO: (REO+SiO₂) between 0.1 and 0.4, more preferably between 0.2 and 0.4, and even more preferably between 0.2 and 0.3.

The REO layer can be formed or deposited by MOCVD, ALD, AVD or PVD deposition technique.

The SiO₂ or SiON layer can be formed or deposited by MOCVD, ALD, AVD or PVD deposition technique.

The SiO₂ or SiON layer can further comprise Sc, Hf or Al.

Alternatively, the REO layer can further comprise Sc, Hf or Al.

Possibly, both the REO layer and SiO₂ (or SiON) layer can further comprise Sc, Hf or Al.

In a preferred method, the metal gate electrode can comprise (or consist of) W, Ta, Ti, Ru, Pt and/or Mo, more particularly can comprise (or consist of) TiN, TaN and/or Ru.

In a preferred method, the substrate can comprise (or consist of) a Ge, SiGe, GaAs, and/or InP layer.

The annealing step can be a post-deposition anneal or a RTA step.

The present disclosure also describes embodiments of a semiconductor device, such as a MOSFET device, obtainable by the methods described herein.

In particular, a preferred MOSFET device comprises:
a semiconductor substrate,
a gate dielectric comprising a SiO₂ or a SiON layer,
upon and contacting the SiO₂ or SiON layer, a rare earth silicate (RES) layer comprising Dy and/or La, and
a metal gate electrode.

The RES layer results from the annealing of the SiO₂ or SiON layer and the REO layer (comprising Dy and/or La) that are deposited (or formed) upon the substrate, the annealing being performed only after having deposited the metal gate electrode.

The SiO₂ or SiON layer can further comprise Sc, Hf or Al.

Alternatively, the RES layer can further comprise Sc, Hf or Al.

Possibly, both the RES layer and SiO₂ (or SiON) layer can further comprise Sc, Hf or Al.

The metal gate electrode can comprise (or consist of) W, Ti, Ta, Pt, Ru and/or Mo, preferably can comprise (or consist of) TiN, TaN and/or Ru.

The substrate can comprise (or consist of) a Ge, SiGe, GaAs, and/or InP layer.

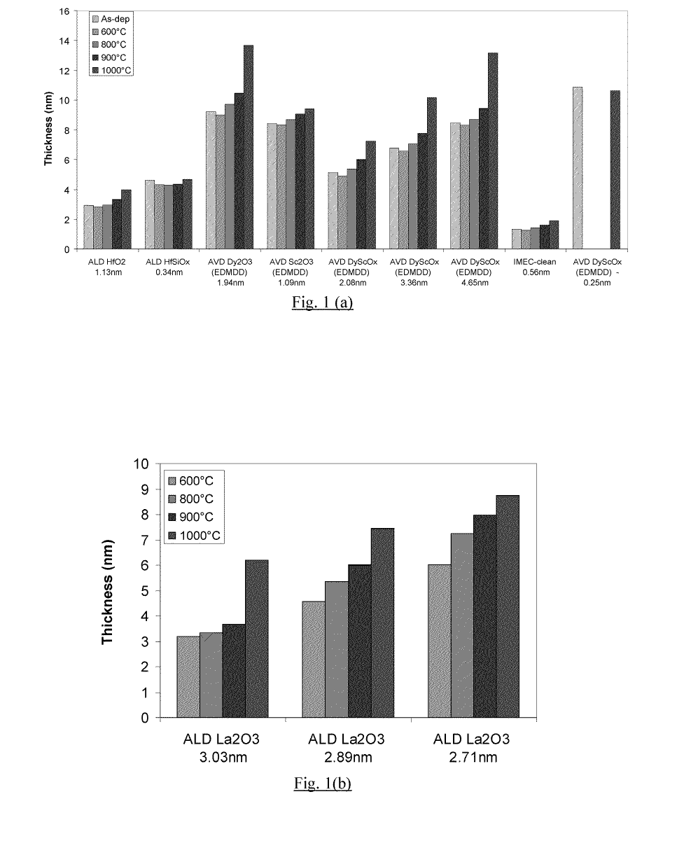

FIG. 1(a) shows the physical thickness variation of the as deposited gate dielectrics upon anneal at different temperatures. On the X-axis are the ellipsometrically measured film thicknesses for the various gate dielectrics. Various deposition techniques like Atomic layer Deposition (ALD) and Atomic Vapor Deposition (AVD) have been employed.

The films have been deposited on an interfacial SiO₂ₓ silicon oxide like interface, which is not distinguishable from the ellipsometer result.

The deposited bi-layer film stack has been annealed at temperatures approximately between 600° C. and 1000° C. in O₂, the later to explicitly stimulate the film thickness increase.

The bar graph for IMEC-clean indicates the silicon substrate oxidation as function of anneal treatment studied (reference). The IMEC-clean is a wet cleaning sequence comprising the steps of organic removal with SOM (Sulphuric acid-Ozone mixture), followed by APM (ammonium peroxide) cleaning and diluted HF/HCl with DI (deionized) water rinses in between and Marangoni drying at the end. This substrate only received a clean thereby forming a chemical oxide.

It can be seen that the thickness increase/layer reaction is thermally activated, the larger the thermal budget the larger the physical thickness, and fully deploying at temperatures of approximately 1000° C. or above. However, the degree of reactivity, i.e. the dependency of physical thickness on thermal budget, clearly depends on the species involved, with Dy (and La, see FIG. 1(b)) reacting more substantially than Sc (or even Si) containing films. Moreover, the reactivity of the Dy containing films can be modulated with Sc addition.

FIG. 1(b) shows the thickness variation of the as-deposited ALD La₂O₃ upon different anneal steps approximately from 600° C. to 1000° C. As is the case with Dy, a clear reactivity and hence physical thickness increase can be observed with the use of La upon thermal annealing. However, as can be seen from FIG. 1(b), La₂O₃ shows a different behavior compared to Dy:
a reactivity at lower temperatures (about 800° C.),
moreover, the thickness increase does not substantially depend on the as deposited thickness of the La₂O₃ layers.

This shows that the (rare earth) element used is one of the parameters that assist in controlling the dielectric properties of the final gate dielectric layer outcome at the end of the process.

When annealing a rare earth oxide (REO) layer or stack of layers deposited on top of silicon oxide, silicate formation can be witnessed for example as:

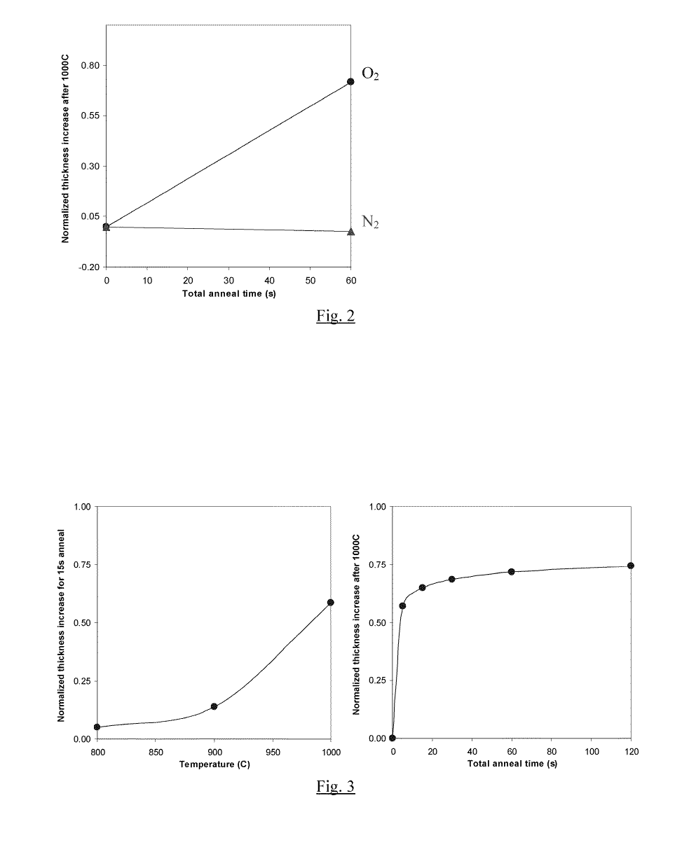

a) in the absence of an additional oxygen supply: a density decrease of the rare earth (RE) oxide layer because of intermixing of the RE oxide with silicon oxide, but without any significant thickness change of the total dielectric stack, as shown in FIG. 2 (N₂ atmosphere);

b) in the presence of an oxygen source: as a thickness increase caused by a volume expansion due to the incorporation of Si or SiO₂, at the reaction front between rare earth film and the silicon oxide film in addition to the regrown or the already-present SiO₂ before deposition as shown in FIG. 2 (O₂ atmosphere).

FIG. 2 shows the normalized thickness increase (t_{annealed}−t_{dep})/t_{dep} for DyScOₓ layers annealed in O₂ (: circle) or N₂ (▴: triangle), where t_{annealed} is the layer thickness after a thermal anneal at about 1000° C. and t_{dep} is the as-deposited thickness of the layer.

Besides the ambient used during the anneal step, the silicate formation is function of the thermal budget applied, such that it depends on time as well as temperature, as shown in FIG. 3.

FIG. 3 shows the normalized thickness increase for an about 10 nm DyScOₓ layer after different thermal treatments (temperature and time).

For the example of DyScOₓ, it is clear that the thickness increases more as temperature goes up, especially at temperatures exceeding about 900° C. It can also be seen that the initial silicate formation occurs very fast before stabilizing to an equilibrium value that can be interpreted as the maximum solubility of SiO₂ in DyScOₓ.

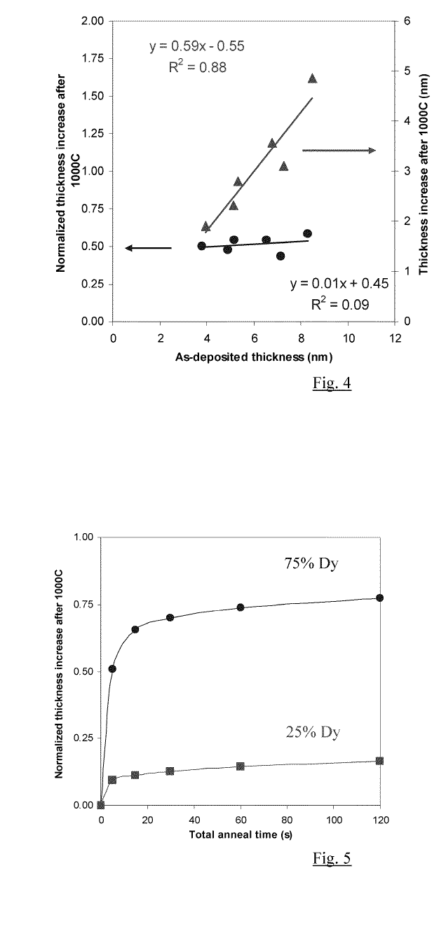

FIG. 4 shows the normalized thickness increase (t_{annealed}−t_{dep})/t_{dep} (: circle) and absolute thickness increase (▴: triangle) after 1000° C. anneal for a DyScOx layer as function of the as-deposited thickness.

FIG. 5 shows the normalized thickness increase (t_{annealed}−t_{dep})/t_{dep} after a 1000° C. anneal for DyScOx layers as function of the anneal time: Dy-rich (about 75% Dy) (: circle); Sc-rich (about 25% Dy) (▪: square).

The maximum amount of SiO₂ that can be incorporated in the gate dielectric film stack will depend on the amount of rare earth material present (see also FIG. 1(a)). This is evidenced by:

a) the relation between the relative thickness increase and the thickness of the as-deposited rare earth oxide, i.e. the thicker the as-deposited layer, the more SiO₂ can be incorporated as shown in FIG. 4. When considering the relative thickness increase it is seen that the system strives to a certain equilibrium composition, based on the graph below. This equilibrium composition is approximately about 2:1 RE:SiO₂. This ratio is determined by the composition of the rare earth layer (see below FIG. 4 for DyScOx) and not by the physical thickness of the layer.

b) the different behavior of ˜10-nm thick DyScOx layers with different composition. The relative thickness increase is seen to depend on the composition of the DyScOx layer, where the Dy-rich layer, i.e. the layer that contains the most Dy, demonstrates a much larger thickness increase as compared to the Sc-rich layer as shown in FIG. 5. This again demonstrates that the amount of SiO₂ that can be incorporated in the stack depends on the amount of Dy present.

The behavior described above corresponds to an unlimited supply of oxygen, in which the anneal treatments are performed in an oxygen ambient. In that case the system will evolve to a condition where the maximum amount of SiO₂ can be incorporated.

An influence is also seen from the element that is incorporated (co-deposited) in the gate dielectric stack.

FIG. 6 shows the relative thickness increase (%) as function of the Dy concentration (%) for two different compounds: DyHfOx (▪: square) and DyScOx (: circle).

Comparing for example DyScOx with DyHfOx layers with varying composition, it is clear that both stacks behave differently as shown in FIG. 6.

Whereas DyScOₓ layers rather behave as Dy₂O₃ layers (extensive silicate formation) except for the more Sc-rich layers, incorporation of Hf is seen to limit the silicate formation (less thickness increase since less SiO₂ incorporation) up to the very Dy-rich DyHfOx layers.

The behavior described above corresponds to an unlimited supply of oxygen.

For the case where the anneal is performed without additional oxygen supply, e.g. anneal in N₂ or for a layer covered (capped) with an oxygen impermeable layer, silicate formation can only occur by mixing of the RE oxide with the SiO₂ present in the underlying layer. This mixing results in a drop of the density of the RE oxide. This density drop is proportional to the ratio of RE/SiO₂. Once all SiO₂ has been able to react, the system will reach a stable state. The state is stable as long as the system is closed, e.g. when the gate dielectric is covered (capped) with a metal gate layer on top preventing exposure of the gate dielectric to oxygen, and/or no further thermal budgets are applied in an oxygen-containing ambient with a magnitude above the threshold for a given gate dielectric layer formed.

To achieve high performance, it is desirable for a metal gate to have a tunable work function with process conditions similar to those of classical silicon technologies. This can be performed by gaining control of the interface polarization between the metal and the dielectric to engineer the gate work function.

In that respect, the introduction of controlled chemical “impurities” at the dielectric/metal interface is a promising approach. The impact of a low concentration [about 10¹³ atm/cm²] of electropositive elements (such as Rb, Sr, Y, Cs, etc.) at the SiO₂/TiN and HfO₂/TiN interfaces has been modeled using a simple approach based on the derivation of the atomic partial charges present at the interface [Smith, J. Chem. Edu, vol 67, p 559, 1990] and on the potential they generate (within a punctual charge treatment). The models revealed that the work function of TiN could be shifted up to about 0.35 eV, depending on both the nature of the chemical elements and the oxide considered.

As a function of thermal budget applied, the interface region between gate electrode and gate dielectric (or gate dielectric stack) can be modified such that an appropriate work function is achieved. Experimental evidence has been gained for this observation through selective introduction of a cap layer—an ultra-thin (sub nanometer) dielectric deposited in between host dielectric and gate electrode—or alternative dielectric stacks. The new dielectrics that have been explored for use as a bulk dielectric or cap layer are combinations of scandium, dysprosium, lanthanum, aluminum, and hafnium.

Results indicate that Al can be used to shift the threshold voltage upwards (of interest for PMOS), as opposed to rare earth elements that were found to shift the threshold voltage to lower values (of interest for NMOS).

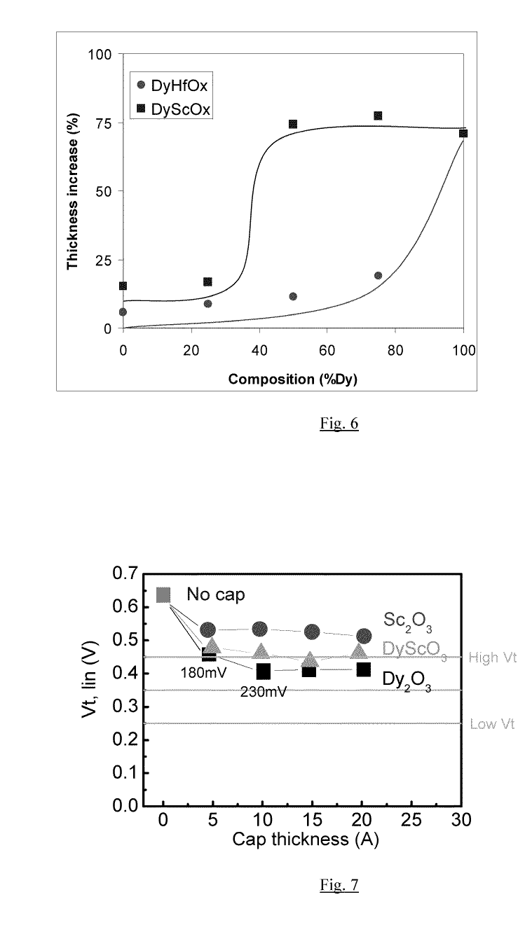

Dy-based oxides show unexpectedly good results when implemented as cap layers. FIG. 7 presents the threshold voltage shift for Dy-based and Sc-based oxides and a combination thereof. The magnitude of the effect is the result of a complex equation with for example the composition of the gate dielectric and metal gate as input parameters.

Further, an example is given on how the parameters can be controlled in order to obtain the targeted EOT and Vt.

The SiO₂ thickness can be controlled through thermal oxidation of the substrate prior to any high-k deposition.

The various nanometer thick high-k dielectric films can be deposited by a range of techniques, preferably chemical vapor deposition and the like, either as nanolaminates or as co-deposited films. The composition of the film can be controlled. The thickness of SiO₂ and composition/thickness of the high-k films ought to be selected such that after application of a thermal budget, a suitable EOT is obtained.

As a demonstration, a SiON dielectric film of thickness 2 nm has been capped by 1 nm of Dy₂O₃ and capped with a TaN metal electrode as shown in FIG. 8(a). After application of a junction activation thermal budget (1030° C.), a gate stack EOT has been extracted, clearly less than the original 2 nm SiON. A reduction in EOT from ˜1.8 nm down to 1.3 nm EOT has been observed, as well as a reduction in Vt as shown in FIG. 8(b). Also, a similar experiment has been done using HfSiON dielectrics with Dy₂O₃ cap.

1. A method for forming a gate stack in a MOSFET device, comprising:
forming, on a semiconductor substrate, a dielectric comprising at least one layer, the dielectric having an upper layer comprising a Si-containing dielectric material;
depositing at least one rare earth oxide layer on the upper layer of the dielectric;
depositing a metal gate electrode material on the rare earth oxide layer; and
only after depositing the metal gate electrode material, annealing the gate stack to form a rare earth silicate layer.

2. A method according to claim 1, wherein the thickness of the rare earth oxide layer is REO, the thickness of the upper layer of the dielectric is Si(CDM), and the ratio REO:( REO+Si(CDM)) is between about 0.1 and about 0.4.

3. A method according to claim 1, wherein the thickness of the rare earth oxide layer is REO, the thickness of the upper layer of the dielectric is Si(CDM), and the ratio REO:( REO+Si(CDM)) is between about 0.2 and about 0.3.

4. A method according to claim 1, wherein the rare earth oxide layer is formed using a deposition technique selected from the group consisting of MOCVD, ALD, AVD and PVD.

5. A method according to claim 1, wherein the rare earth oxide layer comprises one or more rare earth elements selected from the group consisting of La, Y, Pr, Nd, Sm, Eu, Gd, Dy, Er, and Yb.

6. A method according to claim 5, wherein the rare earth oxide layer comprises one or more rare earth oxides selected from the group consisting of La-based oxides and Dy-based oxides.

7. A method according to claim 1, wherein the rare earth oxide layer comprises dysprosium oxide.

8. A method according to claim 1, wherein the rare earth oxide layer comprises dysprosium scandate.

9. A method according to claim 1, wherein the rare earth oxide layer further comprises a modulator element selected from the group consisting of Sc, Hf and Al.

10. A method for forming a gate stack in a MOSFET device comprising:
forming, on a semiconductor substrate, a dielectric comprising at least one layer, the dielectric having an upper layer comprising a Si-containing dielectric material;
depositing at least one rare earth layer on the upper layer of the dielectric;
depositing a metal gate electrode material on the rare earth layer;
preventing oxidation of the rare earth layer; and
only after depositing the metal gate electrode material, annealing the gate stack to form a rare earth silicate layer.

11. A method according to claim 1, wherein the upper layer of the dielectric comprises a high-k material.

12. A method according to claim 1, wherein the upper layer of the dielectric comprises SiO₂.

13. A method according to claim 1, wherein the upper layer of the dielectric consists of SiO₂.

14. A method according to claim 1, wherein the upper layer of the dielectric comprises nitrogen.

15. A method according to claim 14, wherein the upper layer of the dielectric consists of SiON.

16. A method according to claim 1, wherein the annealing step is performed at a temperature between about 600° C. and about 1200° C.

17. A method according to claim 1, wherein the annealing step is performed at a temperature between about 800° C. and about 1200° C.

18. A method according to claim 1, wherein the upper layer of the dielectric is formed using a deposition technique selected from the group consisting of MOCVD, ALD, AVD and PVD.

19. A method according to claim 1, wherein the metal gate electrode material comprises a material selected from the group consisting of W, Ta, TI, Ru, Pt and Mo.

20. A method according to claim 1, wherein the substrate comprises a semiconductor selected from the group consisting of Ge, SiGe, GaAs, and InP.

21. A method according to claim 1, wherein the annealing step is a post-deposition anneal.

22. A method according to claim 1, wherein the annealing step is a Rapid Thermal Anneal.

23. A method according to claim 1, wherein the annealing step is performed at a temperature between about 800° C. and about 1000° C.

24. A MOSFET device having a gate stack comprising:
a semiconductor substrate,
a dielectric on the substrate, the dielectric comprising at least one layer of a Si-containing dielectric material;
a rare earth silicate layer on the layer of Si-containing dielectric material; and
a metal gate electrode on the rare earth silicate layer;
wherein the gate stack is formed by a method comprising:
depositing a rare-earth-containing layer on the layer of Si-containing dielectric material, wherein the rare-earth-containing layer is selected from the group consisting of a rare earth layer and a rare earth oxide layer;
depositing the metal gate electrode on the rare-earth containing layer; and
only after depositing the metal gate electrode, annealing the gate stack to form the rare earth silicate layer.

25. A MOSFET device according to claim 24, further comprising an unreacted rare-earth-containing layer.

26. A MOSFET device according to claim 24, further comprising a polySi layer on the metal gate electrode.

27. A MOSFET device according to claim 24, wherein the Si-containing dielectric material is selected from the group consisting of SiO₂, SiON, HfSiO, and HfSiON.

28. A MOSFET device according to claim 24, wherein the rare-earth-containing layer comprises one or more rare earth elements selected from the group consisting of La, Y, Pr, Nd, Sm, Eu, Gd, Dy, Er, and Yb.

29. A MOSFET device according to claim 24, wherein the rare-earth-containing layer comprises one or more rare earth oxides selected from the group consisting of oxides of La, Y, Pr, Nd, Sm, Eu, Gd, Dy, Er, and Yb.

30. A MOSFET device according to claim 24, wherein the rare-earth-containing layer comprises a rare earth oxide selected from the group consisting of La-based oxides and Dy-based oxides.

31. A MOSFET device according to claim 24, wherein the rare-earth-containing layer comprises dysprosium oxide or dysprosium scandate.

32. A MOSFET device according to claim 24, wherein the metal gate electrode comprises one or more materials selected from the group consisting of W, Ti, Ta, Pt, Ru and Mo.

33. A MOSFET device according to claim 24, wherein the substrate comprises a layer of a semiconductor selected from the group consisting of Ge, SiGe, GaAs, and InP.

34. A method for forming a capacitor comprising:
providing a first electrode material;
forming on the first electrode material a dielectric comprising at least one layer, the dielectric having an upper layer comprising a Si-containing dielectric material
depositing a rare-earth-containing layer on the layer of Si-containing dielectric material, wherein the rare-earth-containing layer is selected from the group consisting of a rare earth layer and a rare earth oxide layer
depositing a second electrode material on the rare-earth-containing layer; and
only after the second electrode material is deposited, annealing the capacitor to form a rare earth silicate.

35. A capacitor comprising:
a first electrode;
a dielectric on the first electrode, the dielectric comprising at least one layer of a Si-containing dielectric material;
a rare earth silicate layer on the layer of Si-containing dielectric material; and
a second electrode on the first electrode;
wherein the capacitor is formed by a method comprising:
depositing a rare-earth-containing layer on the layer of Si-containing dielectric material, wherein the rare-earth-containing layer is selected from the group consisting of a rare earth layer and a rare earth oxide layer;
depositing second electrode on the rare-earth containing layer; and
only after depositing the second electrode, annealing the capacitor to form the rare earth silicate layer.

36. A method according to claim 10, wherein preventing oxidation is performed by maintaining a vacuum at least between the steps of depositing the rare earth layer and depositing the metal gate electrode material.
